(19) United States
(12) Patent Application Publication
(10) Pub. No.: US 2025/0298513 A1
(43) Pub. Date: Sep. 25, 2025

(54) INDEPENDENT REFRESH OF MEMORY DIES BASED ON TEMPERATURE INFORMATION

(71) Applicant: Advanced Micro Devices, Inc., Santa Clara, CA (US)

(72) Inventors: Yubin YAO, Santa Clara, CA (US); Hideki KANAYAMA, Santa Clara, CA (US)

(21) Appl. No.: 18/612,943

(22) Filed: Mar. 21, 2024

(51) Int. Cl. G06F 3/06; G11C 11/406; H01L 25/065; H01L 25/18

(52) U.S. Cl. CPC G06F 3/0617; G06F 3/0653; G06F 3/0673; G11C 11/406; H01L 25/0657; H01L 25/18

(57) ABSTRACT

A memory system includes a first memory die, a second memory die, and a memory controller. The memory controller circuitry is coupled to the first memory die and the second memory die. The memory controller circuitry receives first temperature information corresponding to a temperature of the first memory die, and second temperature information corresponding to a temperature of the second memory die. The memory controller further determines a first refresh rate for the first memory die based on the first temperature information, and a second refresh rate for the second memory die based on the second temperature information. The second refresh rate differs from the first refresh rate.

### TECHNICAL FIELD

Examples of the present disclosure generally relate to independently determining refresh rates for memory integrated circuit dies based on temperature information of the memory integrated circuit dies.

### BACKGROUND

A memory device includes multiple memory integrated circuit (IC) dies. The memory IC dies, or memory dies, are interconnected with each other. A memory controller is coupled to the memory IC dies via channels. The memory controller communicates read/write command signals and refresh signals to the memory IC dies via the channels. The refresh signals instruct the memory IC dies to perform a memory refresh process. The refresh signals control how often a memory refresh process is performed. A memory refresh process includes periodically reading information from an area of a memory IC die, and rewriting the information to the same area. The process of reading and writing the data preserves the data. In a memory IC die, each bit of memory data is stored as the presence or absence of an electric charge on a capacitive element(s). Overtime, the electric charge decreases (e.g., leaks away). The electric charge may decrease to the point where the stored data is lost. Refreshing the data restores the electric charge, preserving the data. A memory refresh cycle is used to repeatedly perform the refresh process.

### SUMMARY

In one example, a memory system includes a first memory die, a second memory die, and a memory controller. The memory controller circuitry is coupled to the first memory die and the second memory die. The memory controller circuitry receives first temperature information corresponding to a temperature of the first memory die, and second temperature information corresponding to a temperature of the second memory die. The memory controller further determines a first refresh rate for the first memory die based on the first temperature information, and a second refresh rate for the second memory die based on the second temperature information. The second refresh rate differs from the first refresh rate.

In one example, a memory controller receives first temperature information corresponding to a temperature of a first memory die and second temperature information corresponding to a temperature of a second memory die. Further, the memory controller determines a first refresh rate for the first memory die based on the first temperature information, and a second refresh rate for the second memory die based on the second temperature information. The second refresh rate differs from the first refresh rate.

In one example, a method includes receiving, at a memory controller, first temperature information corresponding to a temperature of a first memory die, and receiving, at the memory controller, second temperature information corresponding to a temperature of a second memory die. The method further includes determining, at the memory controller, a first refresh rate for the first memory die based on the first temperature information, and determining, at the memory controller, a second refresh rate for the second memory die based on the second temperature information. The second refresh rate differs from the first refresh rate.

These and other aspects may be understood with reference to the following detailed description.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a block diagram of a memory system.

FIG. 2 illustrates a block diagram of a memory device.

FIG. 3 illustrates a flowchart of a method for controlling the refresh of a memory device.

FIG. 4 illustrates a timing diagram of refresh signals for memory dies.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

A memory device includes multiple memory integrated circuit (IC) dies or chips. A memory IC die may be referred to as a memory die. Each memory IC die includes one or more memory cells (e.g., bitcells) that store bit values. The memory device is coupled to a memory controller (memory controller circuitry). The memory controller controls the writing of data to the memory IC dies, the reading of data from the memory IC dies, and the refresh of memory IC dies.

The memory cells of a memory IC die store the bit values as a presence or absence of an electrical charge. For example, a memory cell includes a capacitive element (or elements), and a bit value is stored as a presence or absence of an electrical charge within a capacitive element. The memory cells are refreshed by reading data from the memory cells and writing the data back to the memory cells. Overtime, the capacitive elements of the memory cells leak charge, decreasing the electrical charge stored by the capacitive elements. A memory refresh process refreshes the stored data within the memory cells.

The memory refresh process is periodically performed during a memory refresh cycle. Each memory refresh cycle refreshes an area (e.g., portion) of a memory IC die. The memory refresh process is a background process. Further, while a memory refresh process is performed, the corresponding memory IC die is unavailable for read and write operations.

The memory refresh rate corresponds to how often a memory refresh process is performed. In one or more examples, the memory refresh rate corresponds to the temperature of the memory IC dies of the memory device. For example, as the temperature increases, the amount of charge that leaks from the memory cells of a memory IC die increases. Accordingly, the memory refresh rate is increased. In many memory devices, a common memory refresh rate is used for all of the memory IC dies of the memory device.

The memory refresh process described herein allows for two or more memory IC dies to be independently controlled, and to have respective, and sometimes different, memory refresh rates. In one example, a first temperature signal is received by a memory controller from a first memory IC die and a second temperature signal is received by the memory controller from a second memory IC device. The memory controller determines the refresh rate for the first memory IC die based on the first temperature signal and the refresh rate for the second memory IC die based on the first temperature signal. Thus, the refresh rate for the second memory IC die is determined independently from the refresh rate of the first memory IC die. The refresh rate for the first memory IC die may differ from the refresh rate of the second IC die, and depends on the temperatures of the first and second memory IC dies. In an example where the temperature of the first memory IC die is greater than the temperature of the second memory IC die, the refresh rate for the first memory IC die is increased to be greater than the refresh rate of the second memory IC die.

When a memory IC die is refreshed, the memory IC die is unavailable for read and write commands. Accordingly, a higher memory refresh rate decreases the amount of time a memory IC die is available for performing read and write operations, decreasing the performance memory IC die. In a memory device where a common memory refresh rate for is used for each memory IC die of a memory, as the temperature of one of the memory IC die increases, the refresh rate for all of the other memory IC dies is also increased. However, the temperature of one or more memory IC dies may not necessitate an increase to the corresponding memory refresh rate. The memory refresh process as described in the following allows for the memory refresh rate of two or more memory IC dies to be controlled independently from each other. Accordingly, the performance of the corresponding memory device is increased as compared to memory devices where the refresh rate for all of the memory IC dies is the same. In the memory device as described herein the refresh rate for one or more memory IC dies may be maintained at a lower rate as compare to another memory IC die, increasing the availability of the one or more memory IC die and the corresponding bandwidth.

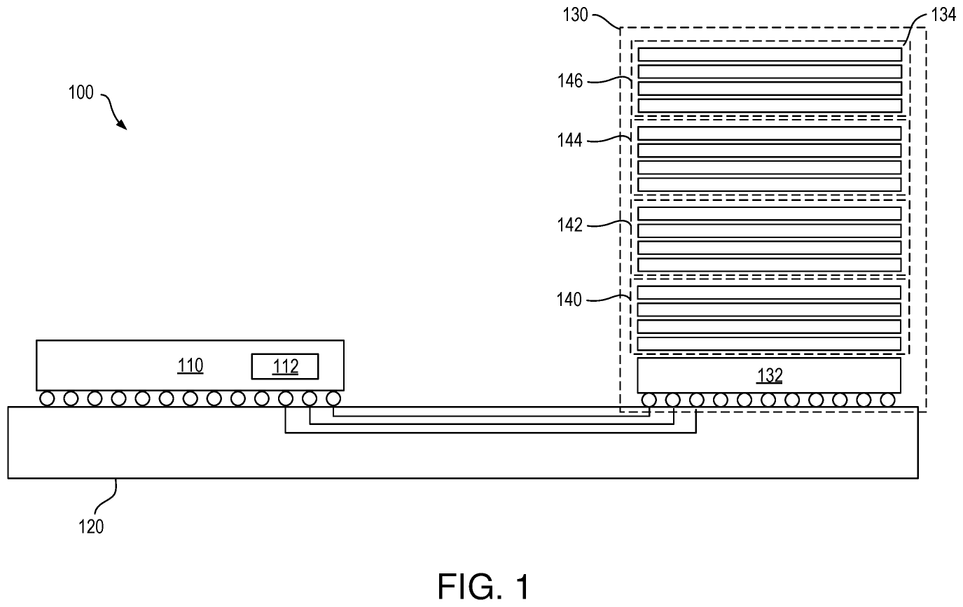

FIG. 1 illustrates an IC system 100. The IC system 100 includes an IC device 110, a substrate 120, and a memory device 130. The IC device 110 is coupled to the memory device 130 through vias and traces disposed within one or more metal layers within the substrate 120.

The IC system 100 may be referred to as a package device. In one or more examples, the IC system 100 may be referred to as a memory system. In one example, the IC system 100 is coupled to another substrate (e.g., a package substrate), and/or to other devices (e.g., processors and/or memory devices).

In one example, the IC device 110 is a processing device or devices. In one or more examples, the IC device 110 represents one or more processing devices. The one or more processing devices may be a microprocessor, a central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets, or processors implementing a combination of instruction sets. In one example, the IC device 110 may be a processing device that is one or more special-purpose processing devices such as an application specific integrated circuit (ASIC), a field programmable gate array (FPGA), a digital signal processor (DSP), network processor, or the like. The IC device 110 may be configured to execute instructions for performing the operations and steps described herein.

In one example, the IC device 110 includes memory controller circuitry 112. The memory controller circuitry 112 generates and outputs control signals for the memory device 130. For example, the memory controller circuitry 112 receives data signals and/or other signals and generates command signals (e.g., read command signals and/or write command signals) and/or control signals (e.g., refresh signals) from the data signals. The command signals and control signals are output to the memory device 130.

The substrate 120 includes one or more metal layers and dielectric layers. A metal layer is disposed between alternating dielectric layers. In one example, the substrate 120 is an interposer. In another example, the substrate 120 is a package substrate. The substrate 120 may be coupled to another substrate. In one or more examples, one or more additional processor devices and/or memory devices are disposed on and/or coupled to the substrate 120.

The memory device 130 includes a logic die 132 and memory dies 134. The memory dies 134 are interconnected with each other and the logic die 132. In one example, the memory dies 134 are vertically stacked on the logic die 132.

The logic die 132 is disposed on the substrate 120. The logic die 132 is communicatively coupled with the IC device 110. In one example, the logic die 132 receives commands from the IC device 110, and communicates the commands to the memory dies 134. In one example, the logic die 132 includes the memory controller circuitry that at least partially controls the memory dies 134 (e.g., generates read command signal, write commands signals, and/or other control signals for the memory dies 134). For example, the memory controller circuitry 112 is included within the logic die 132.

The memory dies 134 may be a non-volatile memory. For example, the memory dies 134 may be random access memories (RAM). In one example, the memory dies 134 are dynamic RAM (DRAM). In another example, the memory dies 134 may be other types of RAM (e.g., field-effect transistor memories, or magnetoresistive memories, among others). In one example, the memory dies are high bandwidth memories (HBM).

The memory dies 134 may be grouped into memory die groups 140, 142, 144, and 146. Each memory die group is identified by an identifier, or stack identifier (SID). For example, the memory die group 140 is assigned SID0, the memory die group 142 is assigned SID1, the memory die group 144 is assigned SID2, and the memory die group 146 is assigned SID3. The SID may be referred to as to the “rank” for a memory die, and is used to identify a particular memory die group when communicating with the memory dies 134.

The memory dies 134 are coupled to the IC device 110 via one or more channels. The channels are used to communicate data signals and controls signals (e.g., read command signals, write command signals, and refresh signals) from the memory controller circuitry 112 to the memory dies 134. In one example, the memory dies 134 are coupled to the IC device 110 via N channels. N is two or more. In one example, N is 16. In other examples, N is greater than or less than 16.

In one example, the one or more channels are used by each memory die of each group 140, 142, 144, and 146 of memory dies 134 to couple with the memory controller circuitry 112 of the IC device 110. For example, each memory die in each group 140, 142, 144, and 146 of the memory dies 134 is coupled to the IC device 110 via a different one or more of the channels. Each memory die within each group 140, 142, 144, and 146 is assigned an SID and one or more channels. The SID and channels are used to communicate signals from the memory controller circuitry 112 to a respective memory die.

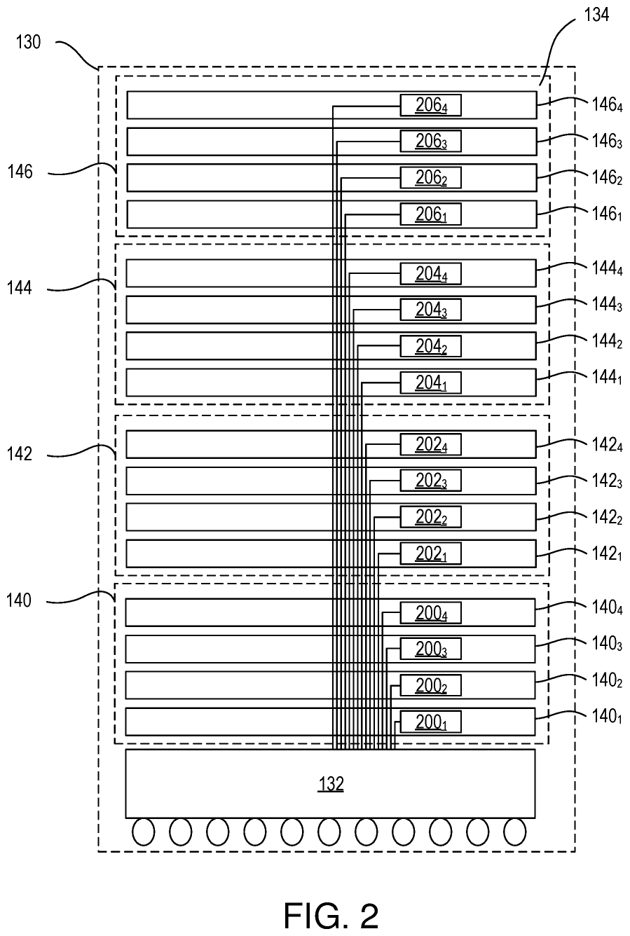

With reference to FIG. 2, the memory dies 134 of the memory device 130 include 16 memory dies 140₁-146₄, grouped into memory die groups 140-146. Each of the memory die groups 140-146 has four memory dies. In other examples, more than or less than four groups may be used, and/or, each group may have more than or less than four memory dies 140₁-146₄.

The memory die group 140 includes memory dies 140₁-140₄. The memory die group 140 is assigned SID0. Further, memory die 140₁ is assigned channels 1-4, the memory die 140₂ is assigned channels 5-8, the memory die 140₃ is assigned channels 9-12, and the memory die 140₄ is assigned channels 13-16.

The memory die group 142 includes memory dies 142₁-142₄. The memory die group 142 is assigned SID1. Further, memory die 142₁ is assigned channels 1-4, the memory die 142₂ is assigned channels 5-8, the memory die 142₃ is assigned channels 9-12, and the memory die 142₄ is assigned channels 13-16.

The memory die group 144 includes memory dies 144₁-144₄. The memory die group 144 is assigned SID2. Further, memory die 144₁ is assigned channels 1-4, the memory die 144₂ is assigned channels 5-8, the memory die 1443 is assigned channels 9-12, and the memory die 144₄ is assigned channels 13-16.

The memory die group 146 includes memory dies 146₁-146₄. The memory die group 146 is assigned SID3. Further, memory die 146₁ is assigned channels 1-4, the memory die 146₂ is assigned channels 5-8, the memory die 146₃ is assigned channels 9-12, and the memory die 146₄ is assigned channels 13-16.

A memory die in each group 140-146 is assigned to a common channel or channels. Accordingly, to communicate with a particular memory die, an SID (or rank) and channel (or channels) are used. For example, SID0 and one or more of the channels 1-4 are used to communicate with the memory die 140₁, and SID1 and one or more of the channels 1-4 are used to communicate with the memory die 142₁.

Each memory die 140₁-146₄ is associated with a temperature sensor 200₁-206₄. The temperature sensors 200₁-206₄ may be disposed within or external to a corresponding memory die 140₁-146₄. In one example, one or more of the temperature sensors 200₁-206₄ are disposed external to the memory dies 134 or the memory device 130. The temperature sensors 200₁-206₄ measure the temperature of a respective memory die 140₁-146₄. The temperature sensor 200₁-206₄ outputs temperature information for a respective memory die 140₁-146₄ to the IC device 110. In one example, the temperature information is output to the logic die 132, and from the logic die 132 to the memory controller circuitry 112. Accordingly, the temperature sensors 200₁-206₄ output temperature information from a corresponding memory die 140₁-146₄ to the memory controller circuitry 112.

The temperature information includes a temperature of a respective memory die 140₁-146₄, a change in temperature for a respective memory die 140₁-146₄, or a value relative to a temperature threshold or threshold. The temperature is in degrees Celsius, Fahrenheit, or another temperature measure.

In one example, the memory controller circuitry 112 sends a request for temperature information for one or more of the memory dies 140₁-146₄. For example, the memory controller circuitry 112 sends a request for temperature information from each of the memory dies 140₁-140₄. In one example, the memory controller circuitry 112 sends a request for temperature information for each channel (e.g., channels 1-16) of each SID (e.g., SID0, SID1, SID2, and SID3). The memory controller circuitry 112 determines, based on the temperature information for each channel and each SID, the temperature for each of the memory dies 140₁-146₄. In one example, the memory controller circuitry 112 has a mapping that indicates which channel or channels and which SID corresponds to which of the memory dies 140₁-146₄. The memory controller circuitry 112 uses the mapping to associate temperature information with a particular memory die 140₁-140₄.

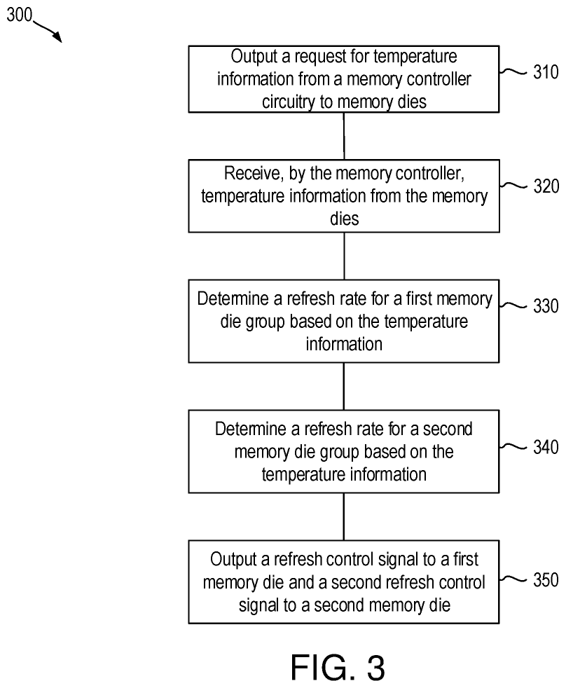

As is described in greater detail in the following, the memory controller circuitry 112 updates a refresh rate of a memory die group 140-146, or a memory die 140₁-146₄ of an SID based on the corresponding temperature information. For example, FIG. 3 illustrates a flowchart of a method 300 for updating the refresh rate of a memory die. While the method 300 is described with regard to the memory controller circuitry 112 of the IC device 110, in other examples, the method 300 may be performed by memory controller circuitry of the logic die 132 and/or other memory controller circuitry coupled to the memory device 130.

At 310 of the method 300, a request for temperature information is output from a memory controller circuitry to memory dies. For example, the memory controller circuitry 112 generates and outputs a request for temperature information to the memory dies 140₁-146₄. In one example, the memory controller circuitry 112 is coupled to the memory dies 140₁-146₄ via a core test interface. The interface enables communication via a test reuse and integration for embedded cores (e.g., memory dies) and associated circuitries interface. An example of a test interface is an IEEE 1500 interface. In other examples, other interfaces may be used that allow for temperature information to be communicated from each memory die 140₁-146₄ to the memory controller circuitry 112.

The temperature information request is sent via the channels for each SID. With reference to FIG. 2, a temperature information request is sent for SID0 and channels 1-16, SID1 and channels 1-16, SID2 and channels 1-16, and SID3 and channels 1-16. In one example, the temperature information request is set via a bitstream, where first bits correspond to SID0 (e.g., memory die group 140) and channels 1-16, second bits correspond to SID1 (e.g., memory die group 142) and channels 1-16, third bits correspond to SID2 (e.g., memory die group 144) and channels 1-16, and third bits correspond to SID3 (e.g., memory die group 148) and channels 1-16. In other examples, other bitstream configurations may be used. The bitstream is communicated from the memory controller circuitry 112 to the memory dies 140₁-146₄.

At 320 of the method 300, the memory controller receives temperature information from the memory dies. For example, the memory controller circuitry 112 receives the temperature information from the memory dies 140₁-146₄. In one example, temperature information is provided for each memory die in each of the memory die groups 140-146. In another example, the temperature information is provided for one of the memory dies in each of the memory die groups 140-146. In one or more examples, the temperature information is provided for one or more memory dies in each of the memory die groups 140-146.

The temperature information may be communicated via a bitstream including first bits corresponding to the temperature information for SID0 (e.g., memory die group 140) and channels 1-16, second bits corresponding to the temperature information for SID1 (e.g., memory die group 142) and channels 1-16, third bits corresponding to the temperature information for SID2 (e.g., memory die group 144) and channels 1-16, and fourth bits corresponding to the temperature information for SID3 (e.g., memory die group 146) and channels 1-16. In other examples, other bitstream configurations may be used.

At 330 of the method 300, a refresh rate is determined for a first memory die group based on the temperature information. For example, the memory controller circuitry 112 determines the refresh rate for one or more of the memory dies 140₁-140₄ of the memory die group 140 based on the corresponding temperature information. The memory controller circuitry 112 receives the temperature information for each SID (e.g., memory die group) and each channel, and associates the temperature information to the respective memory dies 140₁-140₄. For example, the memory die group 140 corresponds to SID0, memory die 140₁ corresponds to channels 1-4, memory die 140₂ corresponds to channels 5-8, memory die 140₃ corresponds to channels 9-14, and memory die 140₄ corresponds to channels 15-16. The memory controller circuitry 112 determines the temperature information (e.g., bits of a bitstream) that is associated with the SID0, and each respective memory die 140₁-140₄. The memory controller circuitry 112 compares the temperature information to one or more temperature thresholds to determine the refresh rate for the SID0 (e.g., memory die group 140) and/or for each memory die 140₁-140₄. In one example, one or more temperature thresholds are used. The number of temperature thresholds may correspond to the number of different refresh rates. In one example, a first temperature threshold indicates a first refresh rate and a second temperature threshold indicates a second refresh rate. A temperature that is less than the first temperature threshold is corresponds to a first refresh rate, a temperature that is greater than the first temperature threshold and less than the second temperature threshold corresponds to a second refresh rate, and a temperature that is greater than the second temperature threshold corresponds to a third refresh rate. The second refresh rate is greater than the first refresh rate, and the third refresh rate is greater than the second refresh rate. In such an example, the memory controller circuitry 112 compares the temperature information to the thresholds to determine a refresh rate for the memory die group 140.

In one or more examples, a lookup table is used to determine a refresh rate from the temperature information. For example, a lookup table includes ranges of temperatures that are associated with different refresh rates. In such an example, the memory controller circuitry 112 compares the temperature information to the ranges of temperatures within the lookup table to determine a refresh rate for the memory die group 140.

In one example, the memory controller circuitry 112 determines a highest temperature for each memory die group 140-146 and uses the highest temperature to determine the refresh rate for the memory die group 140 as described above. In another example, an average temperature is determined from the memory dies of each memory die group 140-146, and the average temperatures are used to determine the refresh rate as described above. In an example, where the memory dies 140₁-146₄ are vertically stacked, the temperature of the top (e.g., most vertical) memory die in each memory die group 140-146 is used to determine the refresh rate as described above. In another example, a refresh rate is determined for each memory die of a memory die group 140-146, based on respective temperature information. Each memory die may be updated with a different respective refresh rate, the highest refresh rate of the memory dies of a memory die group may be used as the refresh rate for the corresponding memory die group, or an average refresh rate of the memory dies of a memory die group may be used as the refresh rate for the corresponding memory die group.

In one example, the memory controller circuitry 112 determines a refresh rate for memory dies 140₁-140₄ of the memory die group 140 based on the temperature information as described above. In another example, the memory controller circuitry 112 determines a different refresh rate for two or more of the memory dies 140₁-140₄ of the memory die group 140 based on the temperature information as described above.

At 340 of the method 300, a refresh rate is determined for a second memory die group based on the temperature information. For example, the memory controller circuitry 112 determines the refresh rate for one or more of the memory dies 142₁-142₄ of the memory die group 142 based on the corresponding temperature information as described above with regard to the memory die group 140.

The memory controller circuitry 112 may further determine a refresh rate for the memory die groups 144 and 146 (e.g., SID2 and SID3) as is described above with regard to 330 and 340 of the method 300.

As can be seen from the above, the memory controller circuitry 112 determines a refresh rate for each memory die group 140-146 independently from each other. For example, the memory die group 140 may be associated with a higher temperature than the memory die group 142, accordingly, the refresh rate for the memory die group 140 is greater than the memory die group 142. In one or more examples, the memory controller circuitry 112 additionally, or alternatively, determines a refresh rate for each memory die 140₁-146₄ of each memory die group 140-146 independent from each other.

At 350 of the method 300, a first refresh control signal is output to a first memory die and a second refresh control signal is output to a second memory die. In one example, the memory controller circuitry 112 outputs a first refresh control signal to a first memory die 140₁-146₄, and a second refresh control signal to a second memory die 140₁-146₄. In one or more examples, the first refresh signal corresponds to a refresh rate that is greater than or less than the refresh rate of the second refresh signal.

In one example, the first memory die is one of the memory dies 140₁-140₄ of the memory die group 140, and the second memory die is one of the memory dies 142₁-142₄ of the memory die group 142. The refresh control signals are generated based on the refresh rates determined at 330 and 340 of the method 300. The refresh control signals are used to independently control the refresh of the memory die groups 140-144. For example, a different refresh control signal is used for each memory die group 140-144. The refresh control signals are based on refresh rates independently determined for each memory die group 140-146. Accordingly, the refresh control signals independently control the refresh rate for each memory die group 140-146.

In another example, the refresh rate for each memory die of each memory die group 140-146 is independently controlled based on a corresponding refresh control signal.

The memory controller circuitry 112 communicates the refresh control signals to the memory device 130. For example, the memory controller circuitry 112 communicates the refresh control signals to the logic die 132, and the logic die routes the refresh control signals to each of the memory dies 140₁-146₄.

The refresh control signals may be communicated to the memory dies 140₁-146₄ via the corresponding channels and SIDs. For example, to output a refresh control signal to the memory die 140₁, the channels 1-4 and SID0 are used as indicators to route the refresh control signal to the memory die 140₁.

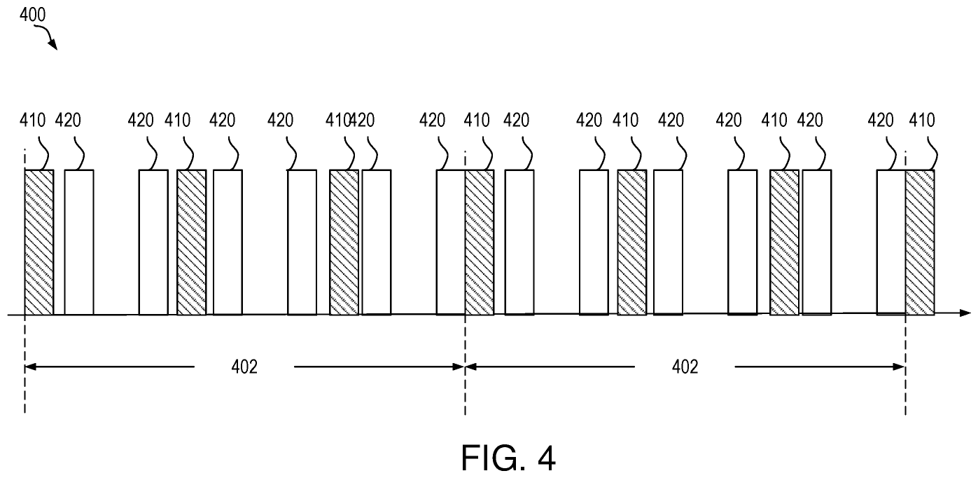

Multiple memory dies may share a common channel. In such an example, the corresponding SID is used to route the refresh control signal to the correct memory die. FIG. 4 illustrates waveform 400. The waveform 400 indicates a refresh control signal 410 for the memory die 140₁ and the refresh control signal 420 for the memory die 142₁. The memory dies 140₁ and 142₁ share a common channel (e.g., channel 1). Accordingly, the control signals 410 and 420 are illustrated as being interleaved with each other in FIG. 4. The control signals 410 and 420 are communicated during the refresh period 402.

The memory refresh process as described in method 300 allows for the refresh process of the memory die groups 140-146 and/or memory dies 140₁-146₄ to be independently controlled. The memory die groups 140-146 and/or the memory dies 140₁-146₄ have respective memory refresh rates. Independently controlling the refresh rates allows for memory dies that have a lower temperature to have a lower refresh rate than memory die that have a higher temperature. The memory dies having a lower refresh rate have a greater availability than a memory die having a higher refresh rate. Accordingly, independently controlling the refresh rates of different memory dies based on temperature improves the performance of the corresponding memory device.

While the foregoing is directed to specific examples, other and further examples may be devised without departing from the basic scope thereof, and the scope thereof is determined by the claims that follow.

1. A memory system comprising:
a first memory die;
a first temperature sensor associated with the first memory die;
a second memory die;
a second temperature sensor associated with the second memory die; and
memory controller circuitry coupled to the first memory die, the first temperature sensor, the second memory die, and the second temperature sensor, wherein the memory controller circuitry is configured to:
receive first temperature information corresponding to a first temperature of the first memory die from the first temperature sensor;
receive second temperature information corresponding to a second temperature of the second memory die from the second temperature sensor;
output a first refresh signal to the first memory die based on a first refresh rate for the first memory die, wherein the first refresh rate is based on the first temperature information; and
output a second refresh signal to the second memory die based on a second refresh rate for the second memory die, wherein the second refresh rate is based on the second temperature information, and wherein the second refresh rate differs from the first refresh rate.

2. The memory system of claim 1 further comprising:
a third memory die, wherein:
the first memory die and the third memory die are associated with a first identifier;
the second memory die is associated with a second identifier;
the first memory die and the second memory die are coupled to the memory controller circuitry via a first channel; and
the third memory die is coupled to the memory controller circuitry via a second controller.

3. The memory system of claim 2, wherein the memory controller circuitry is further configured to receive third temperature information corresponding to a third temperature of the third memory die, and wherein the first refresh rate is further based on the third temperature information, and wherein the first refresh rate is further for the third memory die.

4. The memory system of claim 3, wherein the memory controller circuitry is further configured to:
output the first refresh signal to the third memory die.

5. The memory system of claim 2, wherein the memory controller circuitry is further configured to:
receive third temperature information from the third memory die; and
determine a third refresh rate for the third memory die based on the third temperature information.

6. The memory system of claim 5, wherein the memory controller circuitry is further configured to:
output a third refresh signal to the third memory die based on the third refresh rate.

7. The memory system of claim 1, wherein the first temperature of the first memory die is greater than the second temperature of the second memory die, and wherein the first refresh rate is greater than the second refresh rate.

8. The memory system of claim 1, wherein the first memory die and the second memory die are vertically stacked on each other.

9. A memory controller configured to:
receive first temperature information corresponding to a first temperature of a first memory die from a first temperature sensor associated with the first memory die;
receive second temperature information corresponding to a second temperature of a second memory die from a second temperature sensor associated with the second memory die;
output a first refresh signal to the first memory die based on a first refresh rate for the first memory die, wherein the first refresh rate is based on the first temperature information; and
output a second refresh signal to the second memory die based on a second refresh rate for the second memory die, wherein the second refresh rate is based on the second temperature information, and wherein the second refresh rate differs from the first refresh rate.

10. The memory controller of claim 9, wherein the memory controller is coupled to the first memory die and the second memory die via a first channel, and a third memory die via a second channel, wherein the first memory die and the third memory die are associated with a first identifier, and wherein the second memory die is associated with a second identifier.

11. The memory controller of claim 10 further configured to receive third temperature information corresponding to a third temperature of the third memory die, and wherein the first refresh rate is further based on the third temperature information, and wherein the first refresh rate is further for the third memory die.

12. The memory controller of claim 11 further configured to:
output the first refresh signal to the third memory die.

13. The memory controller of claim 10 further configured to:
receive third temperature information from the third memory die; and
determine a third refresh rate for the third memory die based on the third temperature information.

14. The memory controller of claim 13 further configured to:
output a third refresh signal to the third memory die based on the third refresh rate.

15. The memory controller of claim 9, wherein the first temperature of the first memory die is greater than the second temperature of the second memory die, and wherein the first refresh rate is greater than the second refresh rate.

16. The memory controller of claim 9, wherein the first memory die and the second memory die are vertically stacked on each other.

17. A method comprising:
receiving, at a memory controller, first temperature information corresponding to a first temperature of a first memory die from a first temperature sensor associated with the first memory die;
receiving, at the memory controller, second temperature information corresponding to a second temperature of a second memory die from a second temperature sensor associated with the second memory die;
outputting, from the memory controller, a first refresh signal to the first memory die based on a first refresh rate for the first memory die, wherein the first refresh rate is based on the first temperature information; and
outputting, from the memory controller, a second refresh signal to the second memory die based on a second refresh rate for the second memory die, wherein the second refresh rate is based on the second temperature information, wherein the second refresh rate differs from the first refresh rate.

18. The method of claim 17 further comprising receiving third temperature information corresponding to a temperature of a third memory die, and wherein the first refresh rate is further determined based on the third temperature information, and wherein the first refresh rate is further for the third memory die.

19. The method of claim 17 further comprising:
outputting the first refresh signal to a third memory die.

20. The method of claim 17 further comprising:
receiving third temperature information from a third memory die;
and
outputting a third refresh signal to the third memory die based on a third refresh rate for the third memory die, wherein the third refresh rate is based on the third temperature information.

21. The memory system of claim 3, wherein the first refresh rate is based on an average of the first temperature and the third temperature or a greater one of the first temperature and the third temperature.
